(19) United States
(12) Patent Application Publication
(10) Pub. No.: US 2026/0312485 A1
(43) Pub. Date: Oct. 8, 2026

(54) ISOLATOR CIRCUIT

(71) Applicant: Texas Instruments Incorporated, Dallas, TX (US)

(72) Inventors: Sooping SAW, McKinney, TX (US); John BROZE, Dallas, TX (US); Orlando LAZARO, Cary, NC (US); Timothy MERKIN, Princeton, TX (US)

(73) Assignee: Texas Instruments Incorporated, Dallas, TX (US)

(21) Appl. No.: 19/169,076

(22) Filed: Apr. 3, 2025

(51) Int. Cl. H02M 1/32; H02M 1/088; H03K 17/689

(52) U.S. Cl. CPC H02M 1/32; H02M 1/088; H03K 17/689

(57) ABSTRACT

An apparatus includes a rectifier circuit, first and second capacitors, first and second triangle wave drivers, and a control circuit. The rectifier circuit has a first terminal and a second terminal. The first capacitor has a first terminal coupled to the first terminal of the rectifier circuit, and a second terminal. The second capacitor has a first terminal coupled to the second terminal of the rectifier circuit, and a second terminal. The first triangle wave driver has an input, and an output coupled to the second terminal of the first capacitor. The second triangle wave driver has an input, and an output coupled to the second terminal of the second capacitor. The control circuit has a first output coupled to the input of the first triangle wave driver, and a second output coupled to the input of the second triangle wave driver.

### BACKGROUND

Isolation is useful in electrical circuits to prevent the flow of direct currents and undesirable alternating currents between two parts of a system. While preventing flow of undesirable currents between parts of a system, isolation may allow signal transfer between the isolated parts of the system. Isolation may be provided by integrated circuits referred to as isolators. Electronic systems may include isolators for safety reasons and/or to protect electronic components of the systems. For example, where two systems need to communicate, but the systems have grounds that may be at different potentials, communication may be through an isolator that is tied to the grounds of both systems, but which limits current flow between the grounds. Various types of isolators may include optical coupling, capacitive coupling, inductive coupling, or other types of coupling to isolate systems while allowing communication between the systems.

### SUMMARY

In one example, an apparatus includes a rectifier circuit, first and second capacitors, first and second triangle wave drivers, and a control circuit. The rectifier circuit has a first terminal and a second terminal. The first capacitor has a first terminal coupled to the first terminal of the rectifier circuit, and a second terminal. The second capacitor has a first terminal coupled to the second terminal of the rectifier circuit, and a second terminal. The first triangle wave driver has an input, and an output coupled to the second terminal of the first capacitor. The second triangle wave driver has an input, and an output coupled to the second terminal of the second capacitor. The control circuit has a first output coupled to the input of the first triangle wave driver, and a second output coupled to the input of the second triangle wave driver.

In another example, a circuit includes a capacitive isolator, a rectifier circuit, a first current source, and a second current source. The capacitive isolator has a first input, a second input, a first output, and a second output. The rectifier circuit has a first terminal coupled to the first output of the capacitive isolator, and a second terminal coupled to the second output of the capacitive isolator. The first current source has an input, and an output coupled to the first input of the capacitive isolator. The first current source is configurable to provide a first triangular drive signal at the first input of the capacitive isolator. The second current source has an input, and an output coupled to the second input of the capacitive isolator. The second current source is configurable to provide a second triangular drive signal at the second input of the capacitive isolator.

In a further example, a switch circuit includes a pass transistor, a driver, a rectifier circuit, a capacitive isolator, a first current source, and a second current source. The pass transistor has a first terminal coupled to an input terminal, a second terminal coupled to an output terminal, and a control terminal. The driver has an input, an output coupled to the control terminal of the pass transistor, a voltage terminal, and a reference terminal. The rectifier circuit has a first terminal coupled to the voltage terminal, a second terminal coupled to the reference terminal, a third terminal, and a fourth terminal. The capacitive isolator has a first input, a second input, a first output coupled to the third terminal of the rectifier circuit, and a second output coupled to the fourth terminal of the rectifier circuit. The first current source has an input, and an output coupled to the first input of the capacitive isolator. The first current source is configurable to provide a first triangular drive signal at the first input of the capacitive isolator. The second current source has an input, and an output coupled to the second input of the capacitive isolator. The second current source is configurable to provide a second triangular drive signal at the second input of the capacitive isolator. The second triangular drive signal is an inverse of the first triangular drive signal.

### BRIEF DESCRIPTION OF THE DRAWINGS

FIG. 1 is a block diagram of an example circuit that includes a capacitive isolator and drive circuitry that reduces electromagnetic interference (EMI).

FIG. 2 is a schematic diagram of the circuit of FIG. 1 showing example internal circuitry.

FIG. 3 is a schematic diagram of an example isolated high-side switch circuit using the circuitry of FIG. 2.

FIG. 4 is graphs of common mode noise in the circuit of FIG. 2 versus a reference circuit.

FIG. 5 is a schematic diagram of an example automotive insulation measurement circuit that includes the isolated high-side switch circuit of FIG. 3.

### DETAILED DESCRIPTION

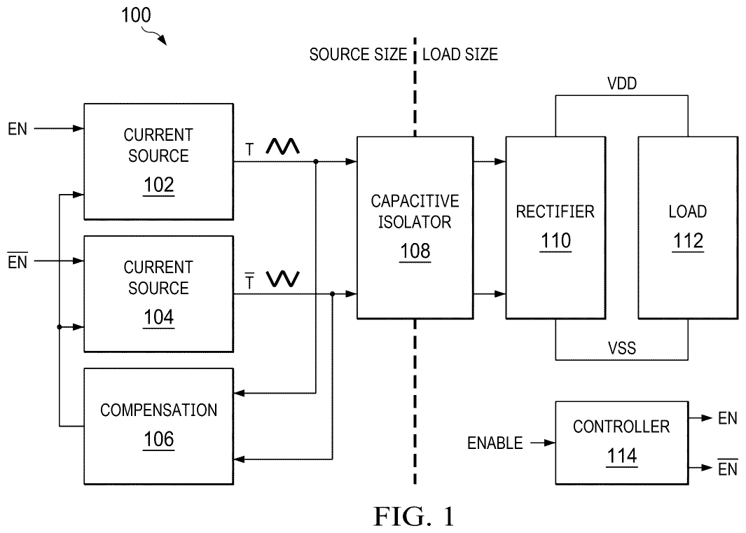

FIG. 1 is a block diagram of an example circuit 100 that includes a capacitive isolator and drive circuitry that reduces electromagnetic interference (EMI). The circuit 100 includes current sources 102 and 104, a compensation circuit 106, a capacitive isolator 108, a rectifier 110, and a load circuit 112. The capacitive isolator 108 capacitively isolates the circuitry on the load side of the capacitive isolator 108 from circuitry on the source side of the capacitive isolator 108. For example, the ground voltage used on the load side of the capacitive isolator 108 may be significantly different from the ground voltage used on the source side of the capacitive isolator 108.

In examples of the circuit 100, the current source 102 and the current source 104 are triangle wave drivers that receive signals EN and. The current sources 102 and 104 provide triangular drive signals T and to the capacitive isolator 108 responsive to EN and. Triangular drive signals are signals that have a linear rise and fall in a symmetrical triangular pattern. The capacitive isolator 108 passes T and to the rectifier 110. The rectifier 110 rectifies the signals received from the capacitive isolator 108, to generate VDD and VSS for powering the load circuit 112. Differences in the slope and/or amplitude of T and can cause undesirable noise on VSS that produces electromagnetic interference (EMI). In the circuit 100, the slope and amplitude of T and are closely matched to reduce common mode noise on VSS and associated EMI.

The load circuit 112 may be any circuit that can be powered by VDD and VSS provided by the rectifier 110. In some examples of the circuit 100, the load circuit 112 may include receiver circuitry and transistor driver circuitry. The load circuit 112 has a first terminal (an input voltage terminal) coupled to the rectifier 110 for reception of VDD, and a second terminal (a reference terminal) coupled to the rectifier 110 for reception of VSS.

The rectifier 110 converts the alternating current (AC) signals received from the capacitive isolator 108 to direct current (DC) for use in powering the load circuit 112. The rectifier 110 has first and second inputs coupled to the capacitive isolator 108, a first output coupled to the first terminal of the load circuit 112, and a second output coupled to the second terminal of the load circuit 112. The rectifier 110 may include full bridge circuitry and filtering in some examples.

The capacitive isolator 108 includes capacitors that pass T and, and block DC. The capacitive isolator 108 has a first output coupled to the first input of the rectifier 110, and a second output coupled to the second input of the rectifier 110. The capacitive isolator 108 has a first input coupled to the current source 102 for receipt of T, and a second input coupled to the current source 104 for receipt of.

The current source 102 generates the triangular signal T responsive to EN. The current source 104 generates the triangular signal responsive to, which may be an inverted (180 degrees phase shifted) version of EN. The current source 102 has a first input coupled to an output of a controller 114 that provides EN. The current source 102 has an output, at which T is provided, coupled to the first input of the capacitive isolator 108. The current source 104 has a first input coupled to an output of the controller 114 which provides. The current source 104 has an output coupled to the second input of the capacitive isolator 108. The controller 114 may provide EN and responsive to receipt of a signal ENABLE at an input of the controller 114. For example, the controller 114 may provide oscillating square wave signals EN and responsive to ENABLE having a logic high state.

Differences in the parasitic capacitances at the outputs of the current source 102 or the current source 104, and the inputs of the capacitive isolator 108 can cause differences in the slopes of T and that increase noise on the load side of the 100. The noise may cause undesirable EMI. To compensate for the differences in parasitic capacitance, the compensation circuit 106 compares T and, and provides feedback to the current source 102 and current source 104. The current source 102 and the current source 104 apply the feedback received from the compensation circuit 106 to adjust T and, and reduce noise and EMI.

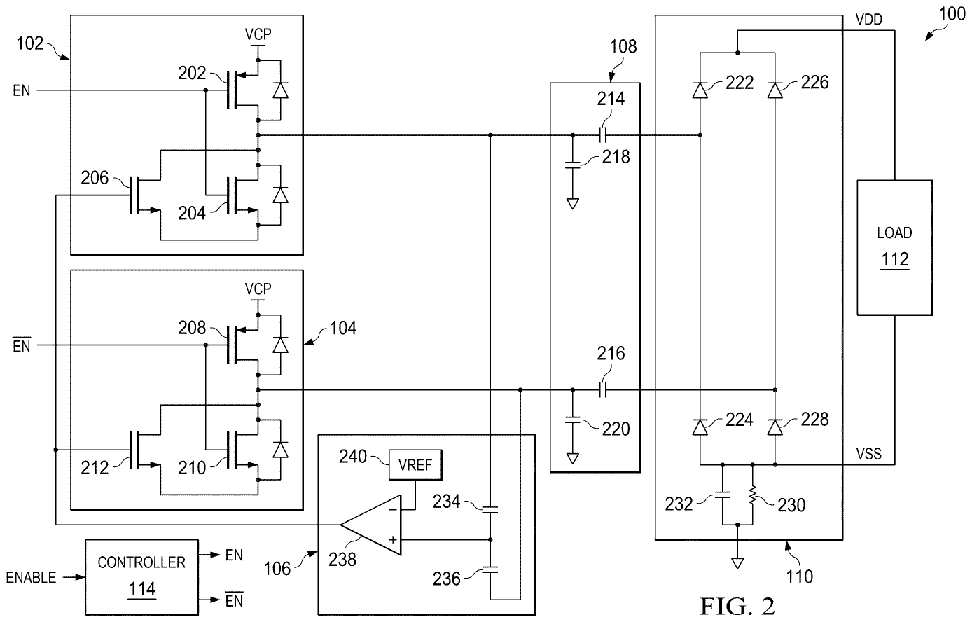

FIG. 2 is a schematic diagram of the circuit 100 showing example internal circuitry of various blocks. The current source 102 includes transistors 202, 204, and 206. The transistor 202 may be a p-channel metal oxide semiconductor field effect transistor (PFET). The transistors 204 and 206 may be n-channel metal oxide field effect transistors (NFETs). Body diodes of the transistors 202 and 204 are shown for reference. The transistor 202 has a first terminal (e.g., source) coupled to an input voltage terminal (VCP). The transistor 202 has a second terminal (e.g., drain) coupled to the first input of the capacitive isolator 108. The current source 102 provides T at the second terminal of the transistor 202. The transistor 202 has a control terminal (e.g., gate) coupled to the controller 114 for receipt of EN. The transistor 204 has a first terminal (e.g., drain) coupled to the second terminal of the transistor 202. The transistor 204 has a second terminal (e.g., source) coupled to a reference terminal (e.g., ground). The transistor 204 has a control terminal (e.g., gate) coupled to the control terminal of the transistor 202. The transistor 202 sources current to generate a rising edge of T based on EN, and the transistor 204 sinks current to generate a falling edge of T based on EN. For example, if EN has a logic low state, then the transistor 202 is turned on to source current and generate a rising edge of T. If EN has a logic high state, then the transistor 204 is turned on to sink current and generate a falling edge of T.

The transistor 206 has a first terminal (e.g., drain) coupled to the first terminal of the transistor 204. The transistor 206 has a second terminal (e.g., source) coupled to the second terminal of the transistor 204, and a control terminal (e.g., gate) coupled to the output of the compensation circuit 106. The transistor 206 sinks current to adjust the falling edge of T based on the compensation signal received from the compensation circuit 106.

The current source 104 includes transistors 208, 210, and 212. The transistor 208 may be a PFET. The transistors 210 and 212 may be NFETs. Body diodes of the transistors 208 and 210 are shown for reference. The transistor 208 has a first terminal (e.g., source) coupled to an input voltage terminal (VCP). The transistor 208 has a second terminal (e.g., drain) coupled to the second input of the capacitive isolator 108. The current source 104 provides at the second terminal of the transistor 208. The transistor 208 has a control terminal (e.g., gate) coupled the controller 114 for receipt of. The transistor 210 has a first terminal (e.g., drain) coupled to the second terminal of the transistor 208. The transistor 210 has a second terminal (e.g., source) coupled to the reference terminal (e.g., ground). The transistor 210 has a control terminal (e.g., gate) coupled to the control terminal of the transistor 208. The transistor 208 sources current to generate a rising edge of based on, and the transistor 210 sinks current to generate a falling edge of based on. For example, if has a logic low state, then the transistor 208 is turned on to source current and generate a rising edge of. If has a logic high state, then the transistor 210 is turned on sink current and generate a falling edge of.

The transistor 212 has a first terminal (e.g., drain) coupled to the first terminal of the transistor 210. The transistor 212 has a second terminal (e.g., source) coupled to the second terminal of the transistor 210, and a control terminal (e.g., gate) coupled to the output of the compensation circuit 106. The transistor 212 sinks current to adjust the falling edge of based on the compensation signal received from the compensation circuit 106.

The compensation circuit 106 includes capacitors 234 and 236, an amplifier 238, and a reference voltage circuit 240. The amplifier 238 has a first input (e.g., an inverting input) coupled to the reference voltage circuit 240. The amplifier 238 has a second input (e.g., a non-inverting input) coupled to the capacitor 234 and the capacitor 236. The amplifier 238 has an output coupled to the control terminals of the transistors 206 and 212. The reference voltage circuit 240 may be a voltage divider, a bandgap circuit, or other circuit that provides a reference voltage for use by the amplifier 238. For example, the reference voltage circuit 240 may include a voltage divider that divides the voltage at VCP by two in some examples of the compensation circuit 106. The reference voltage circuit 240 has an output at which the reference voltage is provided. The output of the reference voltage circuit 240 is coupled to the first input of the amplifier 238.

The capacitor 234 has a first terminal coupled to the first input of the capacitive isolator 108. The capacitor 234 has a second terminal coupled to the second input of the amplifier 238. The capacitor 236 has a first terminal coupled to the second input of the capacitive isolator 108. The capacitor 236 has a second terminal coupled to the second input of the amplifier 238. The amplifier 238 generates an error signal representing the difference of the reference voltage provided by the reference voltage circuit 240 and the sum of T and. The error signal is provided at the output of the amplifier 238 to control the transistor 206 and the transistor 212.

The capacitive isolator 108 includes capacitors 214 and 216. The capacitor 214 has a first terminal coupled to the second terminal of the transistor 202. The capacitor 214 has a second terminal coupled to the first input of the rectifier 110. The capacitor 216 has a first terminal coupled to the second terminal of the transistor 208. The capacitor 216 has a second terminal coupled to the second input of the rectifier 110. The capacitors 218 and 220 represent parasitic capacitance of the transistors 202, 204, 208, 210, and conductors coupling the current source 102 and the capacitive isolator 108 or the current source 104 and the capacitive isolator 108.

In the example of the circuit 100 shown in FIG. 2, the rectifier 110 include a full wave rectifier circuit. The rectifier 110 includes diodes 222, 224, 226, and 228. Parasitic capacitor 232 and parasitic resistor 230 are shown for reference. The diode 222 has a cathode terminal coupled to the first terminal of the load circuit 112. VDD is provided at the cathode of the diode 222. The diode 222 has an anode terminal coupled to the second terminal of the capacitor 214. The diode 224 has a cathode terminal coupled to the anode terminal of the diode 222. The diode 224 has an anode terminal coupled to the second terminal of the load circuit 112. VSS is provided at the anode of the diode 224. The diode 226 has a cathode terminal coupled to the cathode terminal of the diode 222. The diode 226 has an anode terminal coupled to the second terminal of the capacitor 216. The diode 228 has a cathode terminal coupled to the anode terminal of the diode 226. The diode 228 has an anode terminal coupled to the anode terminal of the diode 224 and the second terminal of the load circuit 112.

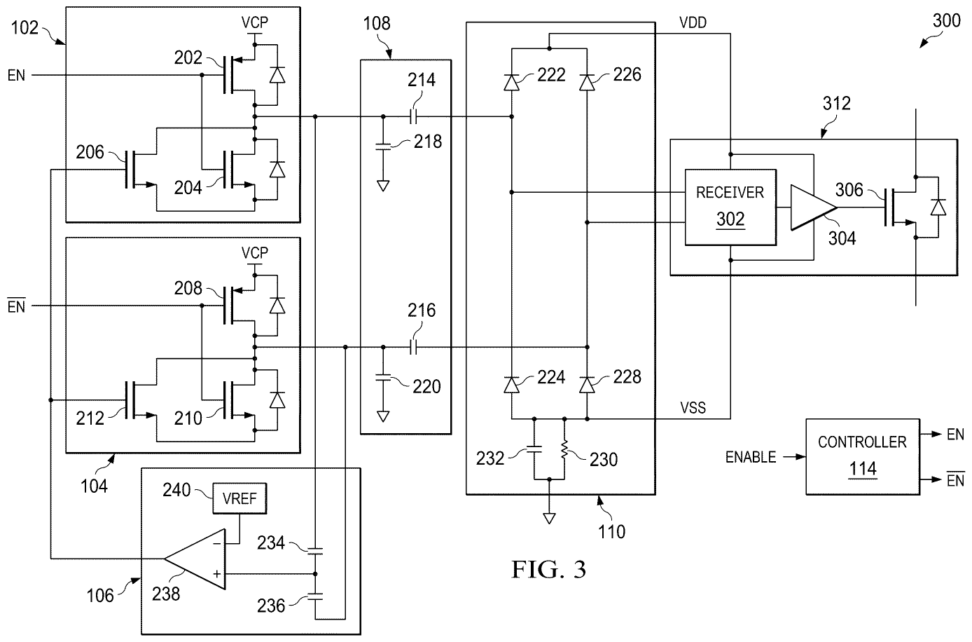

FIG. 3 is a schematic diagram of an isolated high-side switch circuit 300. The isolated high-side switch circuit 300 includes the current source 102, the current source 104, the compensation circuit 106, the capacitive isolator 108, and the rectifier 110 as described with regard to the circuit 100. The isolated high-side switch circuit 300 includes a load circuit 312 coupled to the rectifier 110. The load circuit 312 is an example of the load circuit 112. The load circuit 312 includes a receiver 302, a transistor driver 304, and a transistor 306. The transistor 306 may be an NFET is some examples of the load circuit 312. The transistor 306 is a pass transistor that conducts current between a first external terminal of the isolated high-side switch circuit 300 and a second external terminal of the isolated high-side switch circuit 300. The transistor 306 has a first terminal (e.g., drain) coupled to a first external terminal of the isolated high-side switch circuit 300. The transistor 306 has a second terminal (e.g., source) coupled to a second external terminal of the isolated high-side switch circuit 300. The transistor 306 has a control terminal (e.g., gate) coupled to the transistor driver 304. Control signal received from the transistor driver 304 turns the transistor 306 on or off to enable or disable current flow through the transistor 306.

The transistor driver 304 is powered by VDD and VSS received from the rectifier 110. The transistor driver 304 has an input voltage terminal coupled to the first input of the rectifier 110 for receipt of VDD. The transistor driver 304 has a reference terminal coupled to the second output of the rectifier 110 for receipt of VSS. The transistor driver 304 has an output coupled to the control terminal of the transistor 306. The transistor driver 304 has an input coupled to the receiver 302. If the transistor driver 304 is powered (by VDD and VSS provided by the rectifier 110), the transistor driver 304 generates the control signal provided to the control terminal of the transistor 306 based on a receiver output signal provided ty the receiver 302. The transistor driver 304 generates the control signal with voltage and current suitable for turning the transistor 306 on or off.

The receiver 302 is powered by VDD and VSS received from the rectifier 110. The receiver 302 has an input voltage terminal coupled to the first input of the rectifier 110. The receiver 302 has a reference terminal coupled to the second output of the rectifier 110 for receipt of VSS. The receiver 302 has an output coupled to the input of the transistor driver 304. The receiver 302 has a first input coupled to the first output of the capacitive isolator 108. The receiver 302 has a second input coupled to the second output of the capacitive isolator 108. If the receiver 302 detects differential signal at the first and second inputs of the receiver 302, then the receiver 302 may generate a receiver output signal having a state (e.g., a logic high state) that causes the transistor driver 304 to turn on the transistor 306. If the receiver 302 does not detect a differential signal at the first and second inputs of the receiver 302, then the receiver 302 may generate a receiver output signal having a state (e.g., a logic low state) that causes the transistor driver 304 to turn off the transistor 306.

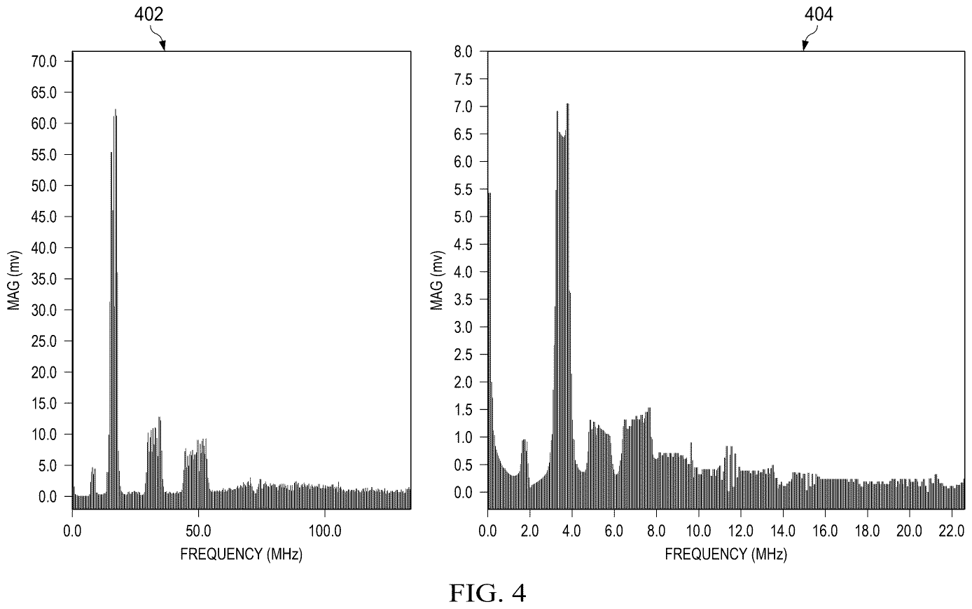

FIG. 4 shows graphs of common mode noise (e.g., noise on VSS) in the circuit 100 versus a circuit lacking the current source 102, the current source 104, and the compensation circuit 106 (i.e., a reference circuit). The graph 402 shows noise generated in the reference circuit with series resistors coupled between the capacitive isolator and the drivers. The series resistors may reduce differences in slew of the driver output signals. The graph 402 shows that the reference circuit produces about 62.5 millivolts of noise.

The circuit 100 reduces noise and EMI by matching the slope and amplitude of the output drive signals (T and) of the current sources 102 and 104. The graph 404 shows that the circuit 100 produces about 7 millivolts of noise. Accordingly, the circuit 100 provides about 19 decibels of nose reduction relative to the reference circuit, with a corresponding reduction in EMI.

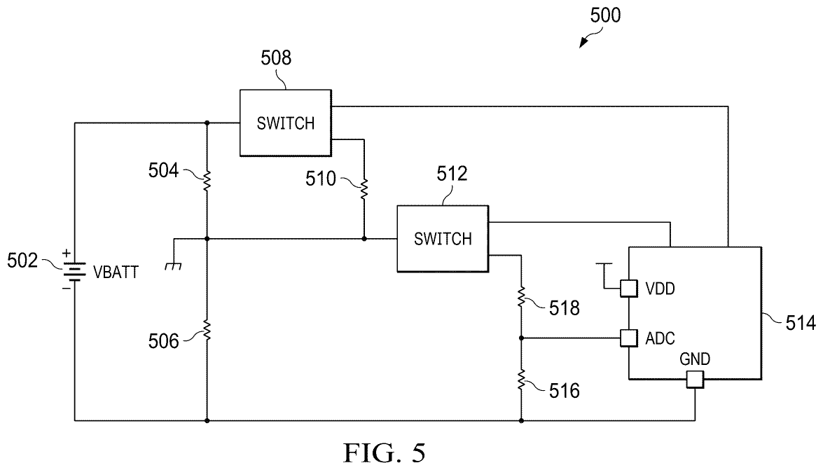

FIG. 5 is schematic diagram of an example automotive insulation measurement circuit 500. The automotive insulation measurement circuit 500 includes a battery 502, resistors 504, 506, 510, 516, and 518, high-side switches 508 and 512, and a controller 514. The high-side switches 508 and 512 may be examples of the isolated high-side switch circuit 300. The battery 502 may be an electric vehicle battery pack that provides a high voltage (e.g., 400-800 volts). The controller 514 may be a microcontroller or other processor.

The battery 502 has a positive terminal and a negative terminal. The resistor 504 is coupled between the positive terminal of the battery 502 and chassis ground. The resistor 506 is coupled between the negative terminal of the battery 502 and chassis ground. The first external terminal of the high-side switch 508 is coupled to the positive terminal of the battery 502. The second external terminal of the high-side switch 508 is coupled to chassis ground via the resistor 510. The resistor 510 has a first terminal coupled to the second external terminal of the high-side switch 508, and a second terminal coupled to chassis ground. A control input of the high-side switch 508 (e.g., the input of the controller 114) is coupled to the controller 514. The high-side switch 508 provides a connection between the positive terminal of the battery 502 and chassis ground.

The first external terminal of the high-side switch 512 is coupled to chassis ground. The second external terminal of the high-side switch 512 is coupled to the controller 514 vial the resistor 518. A control input of the high-side switch 512 (e.g., the input of the controller 114) is coupled to an analog-to-digital converter (ADC) input of the controller 514. The resistor 518 and the resistor 516 are coupled in series between the second external terminal of the high-side switch 512 and the negative terminal of the battery 502. The resistors 516 and 518 form a voltage divider that scales voltages to be measured to a range suitable for measurement by an ADC of the controller 514. The resistor 518 has a first terminal coupled to the second external terminal of the high-side switch 512, and a second terminal coupled to the ADC input of the controller 514. The resistor 516 has a first terminal coupled to the second terminal of the resistor 518, and a second terminal coupled to the negative terminal of the battery 502. The high-side switch 512 provides a connection between chassis ground and the negative terminal of the battery 502.

The controller 514 has a reference terminal coupled to the negative terminal of the battery 502. The controller 514 has an input voltage terminal coupled to a voltage regulator (not shown). The controller 514 has a first output coupled to the control input of the high-side switch 508, and a second output coupled to the control input of the high-side switch 512. The controller 514 makes a first measurement with the high-side switch 508 open and the high-side switch 512 closed, and makes a second measurement with the high-side switch 508 closed and the high-side switch 512 closed. The controller 514 computes the resistance between the positive and negative terminals of the battery 502 and ground based on the two measurements.

FIG. 5 illustrates one example application of the 200. Examples of the circuit 100 may be used to reduce noise and EMI in any application that uses an isolation circuit.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET)) (p-type transistor)), a bipolar junction transistor (BJT-e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a rectifier circuit having a first terminal and a second terminal;
a first capacitor having a first terminal coupled to the first terminal of the rectifier circuit, and a second terminal;
a second capacitor having a first terminal coupled to the second terminal of the rectifier circuit, and a second terminal;
a first triangle wave driver having an input, and an output coupled to the second terminal of the first capacitor;
a second triangle wave driver having an input, and an output coupled to the second terminal of the second capacitor; and
a control circuit having a first output coupled to the input of the first triangle wave driver, and a second output coupled to the input of the second triangle wave driver.

2. The apparatus of claim 1, wherein the first triangle wave driver includes:
a first transistor having a first terminal coupled to an input voltage terminal, a second terminal coupled to the second terminal of the first capacitor, and a control terminal coupled to the first output of the control circuit; and
a second transistor having a first terminal coupled to the second terminal of the first transistor, a second terminal coupled to a reference terminal, and a control terminal coupled to the first output of the control circuit.

3. The apparatus of claim 2, wherein the second triangle wave driver includes:
a third transistor having a first terminal coupled to an input voltage terminal, a second terminal coupled to the second terminal of the second capacitor, and a control terminal coupled to the second output of the control circuit; and
a fourth transistor having a first terminal coupled to the second terminal of the first transistor, a second terminal coupled to a reference terminal, and a control terminal coupled to the second output of the control circuit.

4. The apparatus of claim 3, further comprising:
a third capacitor having a first terminal coupled to the output of the first triangle wave driver, and a second terminal;
an amplifier having a first input coupled to second terminal of the third capacitor; and
a fifth transistor having a first terminal coupled to the first terminal of the second transistor, a second terminal coupled to the second terminal of the second transistor, and a control terminal coupled to the output of the amplifier.

5. The apparatus of claim 4, further comprising:
a fourth capacitor having a first terminal coupled to the output of the second triangle wave driver, and a second terminal coupled to the second terminal of the third capacitor; and
a sixth transistor having a first terminal coupled to the first terminal of the fourth transistor, a second terminal coupled to the second terminal of the fourth transistor, and a control terminal coupled to the output of the amplifier.

6. The apparatus of claim 1, wherein the rectifier circuit includes:
a first rectifier having a first terminal, and a second terminal coupled to the first terminal of the first capacitor;
a second rectifier having a first terminal coupled to the second terminal of the first rectifier, and a second terminal coupled to a reference terminal;
a third rectifier having a first terminal coupled to the first terminal of the first rectifier, and a second terminal coupled to the first terminal of the second capacitor; and
a fourth rectifier having a first terminal coupled to the second terminal of the third rectifier, and a second terminal coupled to the second terminal of the second rectifier.

7. The apparatus of claim 6, further comprising a load circuit having an input voltage terminal coupled to the first terminal of the first rectifier; and a reference terminal coupled to the second terminal of the second rectifier.

8. A circuit, comprising:
a capacitive isolator having a first input, a second input, a first output, and a second output;
a rectifier circuit having a first terminal coupled to the first output of the capacitive isolator, and a second terminal coupled to the second output of the capacitive isolator;
a first current source having an input, and an output coupled to the first input of the capacitive isolator, the first current source configurable to provide a first triangular drive signal at the first input of the capacitive isolator; and
a second current source having an input, and an output coupled to the second input of the capacitive isolator, the second current source configurable to provide a second triangular drive signal at the second input of the capacitive isolator.

9. The circuit of claim 8, wherein the second triangular drive signal is 180 degrees phase-shifted relative to the first triangular drive signal.

10. The circuit of claim 8, wherein the first current source includes:
a first transistor having a first terminal coupled to an input voltage terminal, a second terminal coupled to the first input of the capacitive isolator, and a control terminal coupled to the first output of a control circuit; and
a second transistor having a first terminal coupled to the second terminal of the first transistor, a second terminal coupled to a reference terminal, and a control terminal coupled to the first output of the control circuit.

11. The circuit of claim 10, wherein the second current source includes:
a third transistor having a first terminal coupled to the input voltage terminal, a second terminal coupled to the second input of the capacitive isolator, and a control terminal coupled to a second output of the control circuit; and
a fourth transistor having a first terminal coupled to the second terminal of the third transistor, a second terminal coupled to the reference terminal, and a control terminal coupled to the second output of the control circuit.

12. The circuit of claim 11, further comprising a compensation circuit including:
a first capacitor having a first terminal coupled to the output of the first current source, and a second terminal;
a second capacitor having a first terminal coupled to the output of the second current source, and a second terminal coupled to the second terminal of the second capacitor; and
an amplifier having an input coupled to the second terminal of the first capacitor, and an output coupled to the first current source and the second current source.

13. The circuit of claim 12, wherein:
the first current source includes a fifth transistor having a first terminal coupled to the first terminal of the second transistor, a second terminal coupled to the second terminal of the second transistor, and a control terminal coupled to the output of the amplifier; and
the second current source includes a sixth transistor having a first terminal coupled to the first terminal of the fourth transistor, a second terminal coupled to the second terminal of the fourth transistor, and a control terminal coupled to the output of the amplifier.

14. The circuit of claim 8, wherein the capacitive isolator includes:
a first capacitor having a first terminal coupled to the output of the first current source, and a second terminal coupled to the first terminal of the rectifier circuit; and
a second capacitor having a first terminal coupled to the output of the second current source, and a second terminal coupled to the second terminal of the rectifier circuit.

15. The circuit of claim 8, further including:
a load circuit having a voltage terminal and a reference terminal;
wherein the rectifier circuit has a third terminal coupled to the voltage terminal, and a fourth terminal coupled to the reference terminal.

16. A switch circuit, comprising:
a pass transistor having a first terminal coupled to an input terminal, a second terminal coupled to an output terminal, and a control terminal;
a driver having an input, an output coupled to the control terminal of the pass transistor, a voltage terminal, and a reference terminal;
a rectifier circuit having a first terminal coupled to the voltage terminal, a second terminal coupled to the reference terminal, a third terminal, and a fourth terminal;
a capacitive isolator having a first input, a second input, a first output coupled to the third terminal of the rectifier circuit, and a second output coupled to the fourth terminal of the rectifier circuit;
a first current source having an input, and an output coupled to the first input of the capacitive isolator, the first current source configurable to provide a first triangular drive signal at the first input of the capacitive isolator; and
a second current source having an input, and an output coupled to the second input of the capacitive isolator, the second current source configurable to provide a second triangular drive signal at the second input of the capacitive isolator, where the second triangular drive signal is an inverse of the first triangular drive signal.

17. The switch circuit of claim 16, wherein the capacitive isolator includes:
a first capacitor having a first terminal coupled to the output of the first current source, and a second terminal coupled to the first terminal of the rectifier circuit; and
a second capacitor having a first terminal coupled to the output of the second current source, and a second terminal coupled to the second terminal of the rectifier circuit.

18. The switch circuit of claim 16, wherein:
the first current source includes:
a first transistor having a first terminal coupled to an input voltage terminal, a second terminal coupled to the first input of the capacitive isolator, and a control terminal coupled to the first output of a control circuit; and
a second transistor having a first terminal coupled to the second terminal of the first transistor, a second terminal coupled to a reference terminal, and a control terminal coupled to the first output of the control circuit; and
the second current source includes:
a third transistor having a first terminal coupled to the input voltage terminal, a second terminal coupled to the second input of the capacitive isolator, and a control terminal coupled to a second output of the control circuit; and
a fourth transistor having a first terminal coupled to the second terminal of the third transistor, a second terminal coupled to the reference terminal, and a control terminal coupled to the second output of the control circuit.

19. The switch circuit of claim 18, further comprising a compensation circuit including:
a first capacitor having a first terminal coupled to the output of the first current source, and a second terminal;
a second capacitor having a first terminal coupled to the output of the second current source, and a second terminal coupled to the second terminal of the second capacitor; and
an amplifier having an input coupled to the second terminal of the first capacitor, and an output coupled to the first current source and the second current source.

20. The switch circuit of claim 19, wherein:
the first current source includes a fifth transistor having a first terminal coupled to the first terminal of the second transistor, a second terminal coupled to the second terminal of the second transistor, and a control terminal coupled to the output of the amplifier; and
the second current source includes a sixth transistor having a first terminal coupled to the first terminal of the fourth transistor, a second terminal coupled to the second terminal of the fourth transistor, and a control terminal coupled to the output of the amplifier.
